(19) United States
(12) Patent Application Publication
(10) Pub. No.: US 2016/0358932 A1
(43) Pub. Date: Dec. 8, 2016

(54) GATE-ALL-AROUND VERTICAL GATE MEMORY STRUCTURES AND SEMICONDUCTOR DEVICES, AND METHODS OF FABRICATING GATE-ALL-AROUND VERTICAL GATE MEMORY STRUCTURES AND SEMICONDUCTOR DEVICES THEREOF

(71) Applicant: MACRONIX INTERNATIONAL CO., LTD., Hsinchu (TW)

(72) Inventor: Ta-Hone Yang, Miaoli County (TW)

(21) Appl. No.: 14/730,099

(22) Filed: Jun. 3, 2015

(51) Int. Cl. H01L 27/115; H01L 21/768; H01L 29/51; H01L 21/28; H01L 21/311

(52) U.S. Cl. CPC H01L 27/11582; H01L 27/11565; H01L 27/11568; H01L 21/28282; H01L 21/31111; H01L 29/513; H01L 29/518; H01L 21/76802; H01L 21/76877

(57) ABSTRACT

Present example embodiments relate generally to methods of fabricating a three-dimensional gate-all-around vertical gate semiconductor structure comprising forming a plurality of layers over a substrate, the plurality of layers having alternating first insulative material layers and conductive material layers; identifying bit line and word line locations for the formation of bit lines and word lines; removing portions of the plurality of layers outside of the identified bit line and word line locations; forming vertical second insulative material structures in areas outside of the identified bit line and word line locations; removing portions of the plurality of layers in areas along the identified word line locations outside of the identified bit line locations; removing the first insulative material from the first insulative material layers in areas along the identified word line locations; forming bit lines in the identified bit line locations; and forming word lines in the identified word line locations.

### BACKGROUND

The present disclosure relates generally to semiconductor devices, and more specifically, relates to semiconductor structures and devices, including three-dimensional (3D) gate-all-around (GAA) vertical gate (VG) structures in semiconductor devices and semiconductor devices thereof, and methods of fabricating such semiconductor structures and devices.

There is an ever growing need by semiconductor device manufacturers to further shrink the critical dimensions of semiconductor structures and devices, to achieve greater storage capacity in smaller areas, and to do so at lower costs per bit. Three-dimensional (3D) semiconductor devices using, for example, thin film transistor (TFT) techniques, charge trapping memory techniques, and cross-point array techniques, have been increasingly applied to achieve the above needs by semiconductor manufacturers. Recent developments in semiconductor technology have included the fabrication of vertical structures in semiconductor devices in the form of 3D vertical channel (VC) structures and 3D vertical gate (VG) structures.

### BRIEF SUMMARY

Despite recent developments in the fabrication of semiconductor devices, it is recognized in the present disclosure that one or more problems may be encountered in fabricated three-dimensional (3D) semiconductor devices. For example, the formation of the various layers and structures of 3D vertical channel (VC) structures generally requires a relatively large footprint (or area). Furthermore, such fabricated 3D VC structures often encounter reliability problems and undesirable variations in performance. In respect to 3D vertical gate (VG) structures, although 3D VG structures generally require smaller footprints (or areas) in comparison to 3D VC structures and other fabricated semiconductor devices, the reliable fabrication, including patterning and etching of the vertical gates of such devices and fabricating such devices free of deformation, defects, and/or bending, is oftentimes difficult to achieve. Furthermore, it is recognized in the present disclosure that the programming capability of present 3D VG structures can be improved. For example, present 3D VG structures presently lack gate-all-around (GAA) structures, including charge storage layers formed in bit lines of the 3D VG structures. In this regard, present 3D VG structures are unable to provide for E-field enhancements to the 3D VG structures.

Present example embodiments relate generally to semiconductor devices and methods of fabricating semiconductor devices that address one or more problems in fabricated semiconductor devices, including those described above and in the present disclosure.

In an exemplary embodiment, a method of fabricating a three-dimensional gate-all-around (GAA) vertical gate (VG) semiconductor structure comprising providing a substrate and forming a plurality of layers over the substrate. The plurality of layers have alternating first insulative material layers and conductive material layers, and the first insulative material layers are formed by a deposition of first insulative material and the conductive material layers formed by a deposition of conductive material. The method further comprises identifying bit line and word line locations for the formation of bit lines and word lines. The method further comprises removing portions of the plurality of layers outside of the identified bit line and word line locations. Each of these removed portion extend through the plurality of layers to at least a top surface of the substrate. The method further comprises forming vertical second insulative material structures in areas outside of the identified bit line and word line locations. The method further comprises removing portions of the plurality of layers in areas along the identified word line locations outside of the identified bit line locations. Each of these removed portion extend through the plurality of layers to at least a top surface of the substrate. The method further comprises removing the first insulative material from the first insulative material layers in areas along the identified word line locations. The method further comprises forming bit lines in the identified bit line locations. The bit lines are formed by rounding at least a portion of each of the conductive material layers along the identified bit line locations. The bit lines are further formed by forming a charge storage layer over at least a portion of the rounded conductive material layers. The method further comprises forming word lines in the identified word line locations.

In another exemplary embodiment, a semiconductor structure comprises a three-dimensional gate-all-around (GAA) vertical gate (VG) structure having a plurality of bit lines and word lines formed over a substrate. The semiconductor structure further comprises a plurality of first insulative material portions extending vertically from at least a top surface of the substrate. The plurality of first insulative material portions are formed adjacent to the three-dimensional vertical gate structure and are operable to provide electrical isolation between adjacent word lines of the three-dimensional GAA VG structure.

### BRIEF DESCRIPTION OF THE DRAWINGS

For a more complete understanding of the present disclosure, example embodiments, and their advantages, reference is now made to the following description taken in conjunction with the accompanying drawings, in which like reference numbers indicate like features, and:

FIG. 1 is an example embodiment of a method of fabricating a three dimensional semiconductor device;

FIG. 2A is a method of fabricating an example embodiment of a three-dimensional gate-all-around (GAA) vertical gate (VG) semiconductor structure;

FIG. 2B is a cross-sectional view of an example embodiment of alternating insulative material layers and conductive material layers formed over a substrate;

FIG. 2C is a top view of an example embodiment of identifying bit line and word line locations;

FIGS. 2D-J are illustrative views of an example embodiment of a method of fabricating an example embodiment of a semiconductor device;

FIG. 3A is a method of fabricating another example embodiment of a three-dimensional gate-all-around (GAA) vertical gate (VG) semiconductor structure;

FIG. 3B is a cross-sectional view of another example embodiment of alternating insulative material layers and conductive material layers formed over a substrate;

FIG. 3C is a top view of another example embodiment of identifying bit line and word line locations;

FIGS. 3D-I are illustrative views of another example embodiment of a method of fabricating an example embodiment of a semiconductor device;

FIG. 4A is a method of fabricating another example embodiment of a three-dimensional gate-all-around (GAA) vertical gate (VG) semiconductor structure;

FIG. 4B is a cross-sectional view of another example embodiment of alternating insulative material layers and conductive material layers formed over a substrate;

FIG. 4C is a top view of another example embodiment of identifying bit line and word line locations; and

FIGS. 4D-I are illustrative views of another example embodiment of a method of fabricating an example embodiment of a semiconductor device.

Although similar reference numbers may be used to refer to similar elements in the figures for convenience, it can be appreciated that each of the various example embodiments may be considered to be distinct variations.

Example embodiments will now be described with reference to the accompanying drawings, which form a part of the present disclosure, and which illustrate example embodiments which may be practiced. As used in the present disclosure and the appended claims, the terms “example embodiment,” “exemplary embodiment,” and “present embodiment” do not necessarily refer to a single embodiment, although they may, and various example embodiments may be readily combined and/or interchanged without departing from the scope or spirit of example embodiments. Furthermore, the terminology as used in the present disclosure and the appended claims is for the purpose of describing example embodiments only and is not intended to be limitations. In this respect, as used in the present disclosure and the appended claims, the term “in” may include “in” and “on,” and the terms “a,” “an” and “the” may include singular and plural references. Furthermore, as used in the present disclosure and the appended claims, the term “by” may also mean “from,” depending on the context. Furthermore, as used in the present disclosure and the appended claims, the term “if” may also mean “when” or “upon,” depending on the context. Furthermore, as used in the present disclosure and the appended claims, the words “and/or” may refer to and encompass any and all possible combinations of one or more of the associated listed items.

### DETAILED DESCRIPTION

Despite recent developments in the fabrication of semiconductor devices, it is recognized in the present disclosure that one or more problems may be encountered in the fabrication of three-dimensional (3D) semiconductor devices, and in the fabricated three-dimensional (3D) semiconductor devices themselves. For example, the formation of the various layers and structures of 3D vertical channel (VC) structures generally requires a relatively large footprint (or area). Furthermore, such fabricated 3D VC structures often encounter reliability problems and undesirable variations in performance. In respect to 3D vertical gate (VG) structures, although 3D VG structures generally require smaller footprints (or areas) in comparison to 3D VC structures and other fabricated semiconductor devices, the reliable fabrication, including patterning and etching of the vertical gates of such devices and fabricating such devices free of deformation, defects, and/or bending, is oftentimes difficult to achieve.

It is also recognized in the present disclosure that the resulting programming capability of existing fabricated 3D VG structures can be improved. For example, known 3D VG structures have not been fabricated having or incorporating gate-all-around (GAA) structures, including charge storage layers in bit lines having a tunnel oxide layer formed over a conductive core, a charge trapping layer formed over the tunnel oxide layer, and a block oxide layer formed over the charge trapping layer. Therefore, known 3D VG structures are unable to provide for E-field enhancements to the 3D VG structures. In particular, known 3D VG structures are unable to provide E-field enhancements to the tunnel oxide layer and/or E-field retardation to the block oxide layer of corresponding charge storage layers.

Semiconductor devices and structures, including three-dimensional (3D) gate-all-around (GAA) vertical gate (VG) devices and structures, and methods of fabricating such semiconductor devices and structures are described in the present disclosure for addressing one or more problems encountered in semiconductor devices and structures, including those described above and herein. It is to be understood in the present disclosure that the principles described herein can be applied outside the context of NAND-type and NOR-type devices, including floating gate memory devices, charge trapping memory devices, non-volatile memory devices, and/or embedded memory devices.

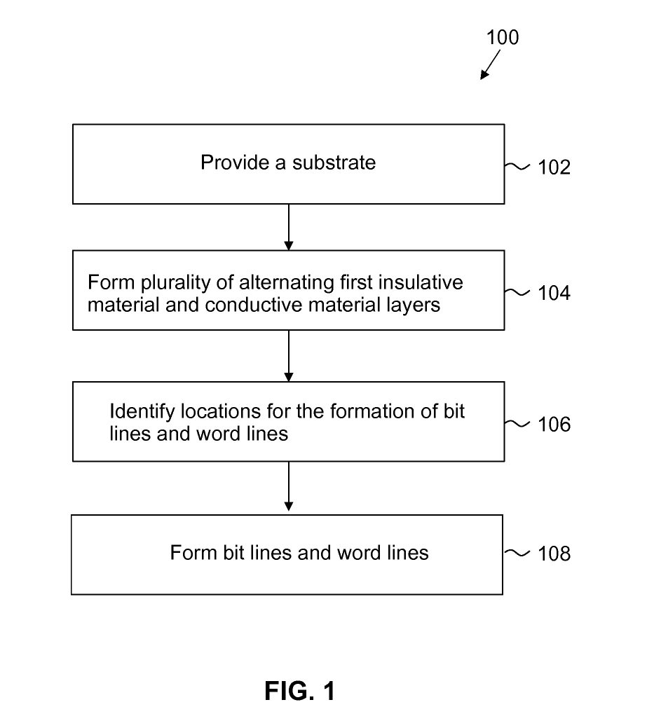

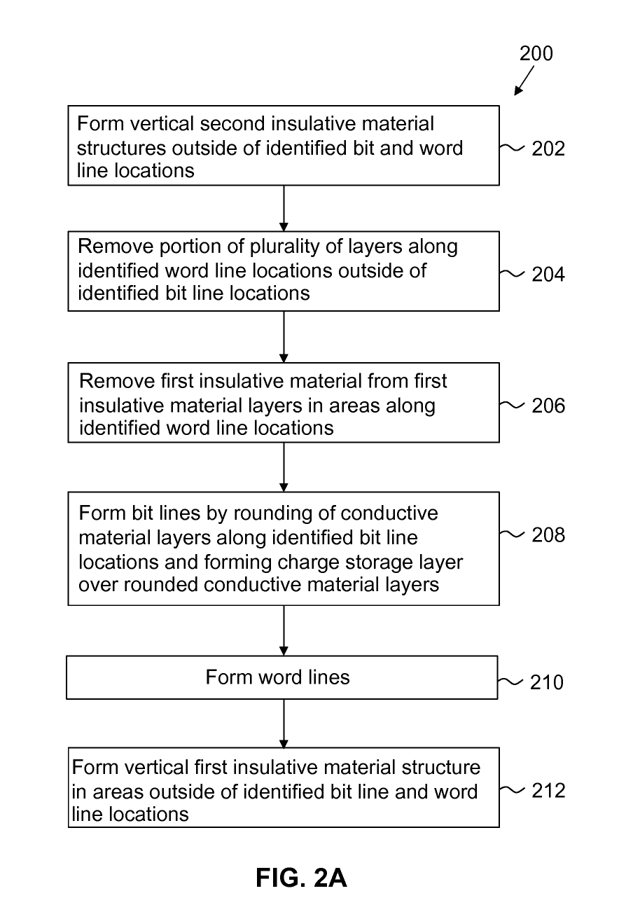

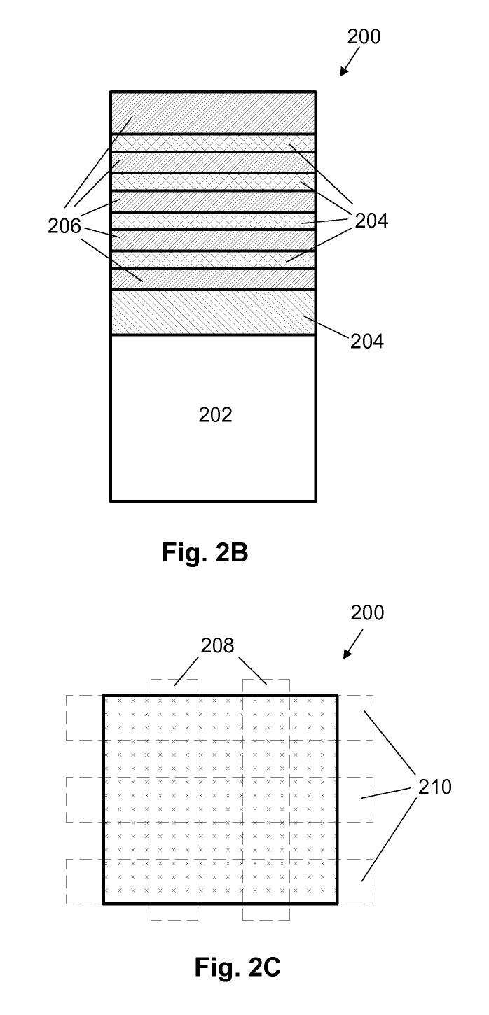

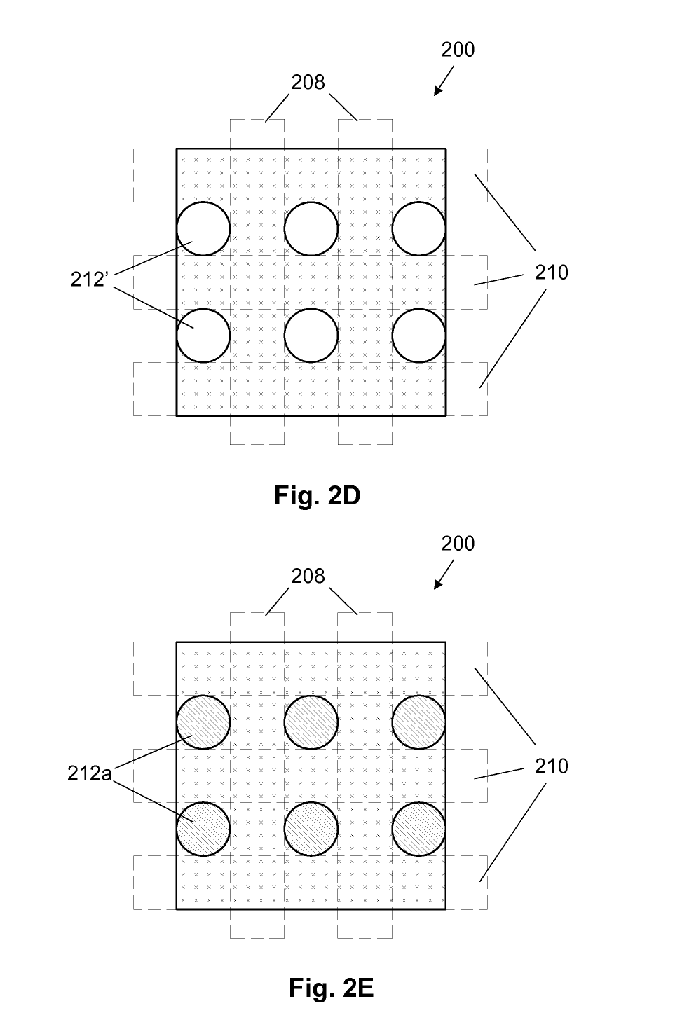

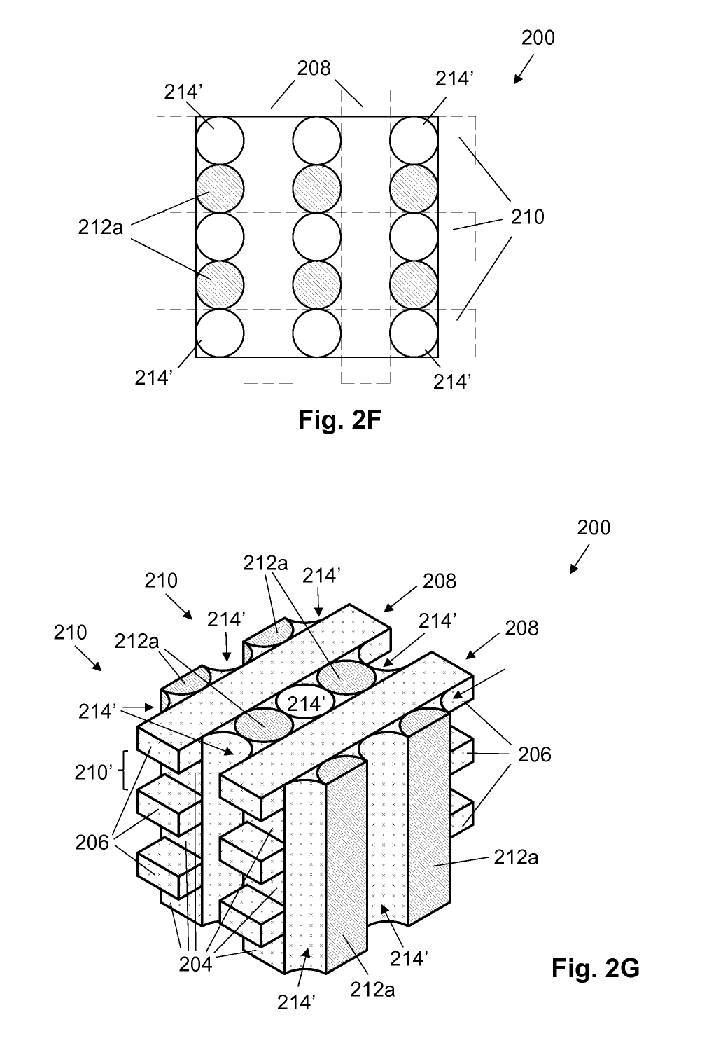

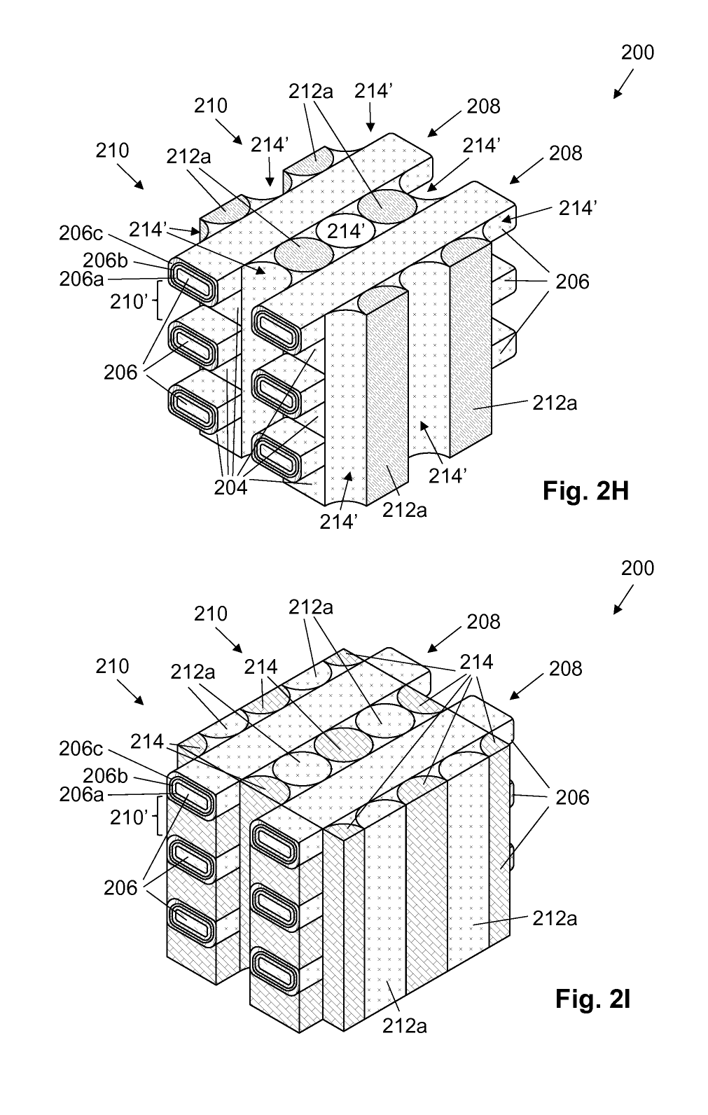

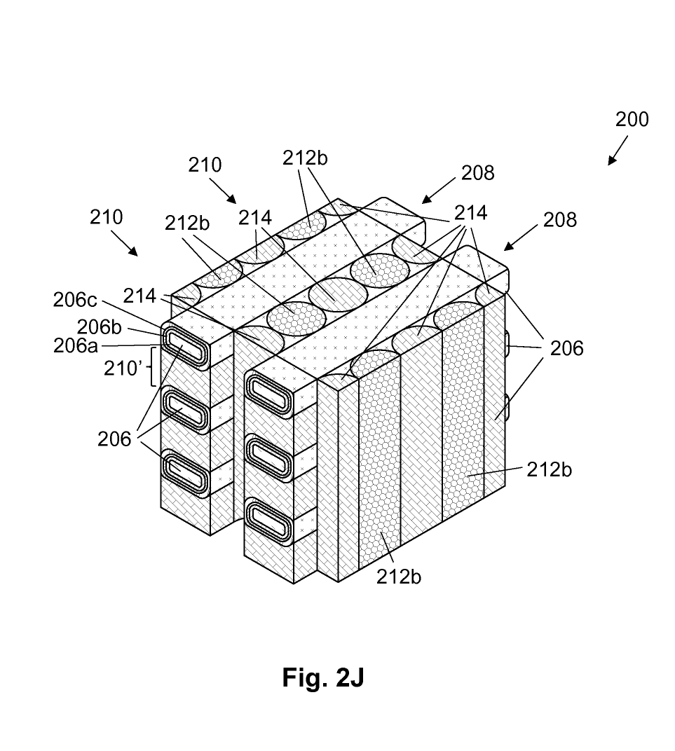

Example embodiments of methods for fabricating example embodiments of semiconductor devices, such as 3D GAA VG structures, are depicted in FIGS. 1-4. As illustrated in the sequence of actions of FIG. 1, an example embodiment of a method 100 may include providing a substrate at action 101. An example embodiment of a method 100 may further include forming a plurality of layers over the substrate at action 103. The plurality of layers may comprise alternating first insulative material layers and conductive material layers. The first insulative material layers may be formed by a deposition of first insulative material and the conductive material layers may be formed by a deposition of conductive material. Cross-sectional views of example embodiments of alternating first insulative material layers 204 and conductive material layers 206 formed over a substrate 202 are illustrated in FIGS. 2B, 3B, and 4B. The first insulative materials may include oxides, nitrides, and the like, and the conductive materials may include polysilicon, and the like.

An example embodiment of a method 100 may further include identifying bit line and word line locations for the formation of bit lines and word lines at action 105. Top views of example embodiments of identifying bit line 208 and word line 210 locations are illustrated in FIGS. 2C, 3C, and 4C.

The method 100 may further include forming bit lines and word lines at action 107 for the 3D GAA VG semiconductor device and/or structure. It is recognized in the present disclosure that present example embodiments are operable to provide E-field enhancements, including E-field enhancements to the 3D GAA VG semiconductor device and/or structure, and are also operable to prevent and/or significantly eliminate the occurrence of deformation, distortion, and/or bending in the vertical structures of the semiconductor device, as well as the formation of stringers. Furthermore, example embodiments of the vertical insulative material structures may provide reductions in or absence of the occurrences of stringers and/or deformities, defects, and/or bending of the vertical structures in the semiconductor devices.

Example embodiments of a semiconductor device, such as a 3D VG device, may be fabricated according to one or more of the above actions, may also include additional actions, may be performable in different sequences, and/or one or more of the actions may be combinable into a single action or divided into two or more actions. Semiconductor devices other than NAND-type and NOR-type devices are also contemplated in example embodiments without departing from the teachings of the present disclosure. Example embodiments of these actions and semiconductor devices will now be described with references to FIGS. 1-4.

### First Example Embodiment

(1) Providing a Substrate (e.g., Action 101).

As described in action 101 of FIG. 1, substrates 202 appropriate for use in semiconductor devices and structures may be obtained by any one or more manufacturing methods, such as pressing methods, float methods, down-drawn methods, redrawing methods, fusion methods, and/or the like.

(2) Forming a Plurality of Alternating First Insulative Material Layers and Conductive Material Layers (e.g., Action 103).

As described in action 103 of FIG. 1, a substrate 202, such as one obtained from the above action 101, may be provided with alternating first insulative material layers 204 and conductive material layers 206 thereon (e.g., action 103), as illustrated in the cross-sectional view of FIG. 2B. The first insulative materials may include oxides, and the like, and the conductive materials may include polysilicon, or the like. The thickness of each of the first insulative material layers 204 may be about 600 Angstroms. It is recognized herein that the thickness of each of the first insulative material layers 204 may be about 500-700 Angstroms in example embodiments. The thickness of each of the conductive material layers 206 may be about 200 Angstroms. It is recognized herein that the thickness of each of the conductive material layers 206 may be about 100-300 Angstroms in example embodiments.

(3) Identifying Word Line and Bit Line Locations (e.g., Action 105).

As described in action 105 of FIG. 1, a substrate 202 having alternating first insulative material layers 204 and conductive material layers 206 formed thereon may be subjected to an identification (or planning or designing) process whereby bit line locations 208 and word line 210 locations are identified (or planned or designed) for subsequent actions (as described below and herein), including the forming of bit lines 208, word lines 210, and vertical first insulative material structures provided substantially or mostly outside of identified bit line and word line locations. An example identification of bit line 208 and word line 210 locations is illustrated in the top view illustration of FIG. 2C.

(4) Forming 3D GAA VG Structures, Including Bit Lines and Word Lines (e.g., Actions 201, 203, 205, 207, 209, and 211).

Reference is now made to the sequence of actions of FIG. 2A. The 3D GAA VG structures may be fabricated by forming vertical second insulative material structures 212a outside of the identified bit line locations 208 and word line locations 210 (e.g., action 201). This may be accomplished by first removing portions 212′ of the plurality of layers outside of the identified bit line locations 208 and word line locations 210, as illustrated in FIG. 2D. Each of these removed portions 212′ may extend through the plurality of layers to at least a top surface of the substrate 202. Although the removed portions 212′ are illustrated in FIG. 2D as resembling circular or cylindrical holes, it is to be understood in the present disclosure that the removed portions 212′ may be in other shapes and/or forms, including squares, rectangles, ovals, etc. Thereafter, as illustrated in FIG. 2E, the vertical second insulative material structures 212a may be formed in areas outside of the identified bit line locations 208 and word line locations 210 by depositing second insulative material in the aforementioned removed portions 212′ depicted in FIG. 2D. In an example embodiment, the second insulative material may be any insulative or dielectric material, such as a nitride, that differs from the first insulative material, such as an oxide, and vice versa, that allows an easy removal of either the first or second insulative material without removing the other.

As illustrated in FIG. 2F, portions 214′ of the plurality of layers in areas along the identified word line locations 210 that are outside of the identified bit line locations 208 may be removed (e.g., action 203). Each of these removed portion 214′ may extend through the plurality of layers to at least a top surface of the substrate 202. Although the removed portions 214′ are illustrated in FIG. 2F as resembling circular or cylindrical holes, it is to be understood in the present disclosure that the removed portions 214′ may be in other shapes and/or forms, including squares, rectangles, ovals, etc.

In action 205, portions 210′ of the first insulative material in the first insulative material layers that are along the identified word line locations 210 may be removed. This is illustrated in FIG. 2G. The aforementioned removal may be achieved by performing an isotropic etching process to remove the first insulative material from the first insulative material layers 204 in areas along the identified word line locations 210. It is recognized in the present disclosure that the vertical second insulative material structures 212a may be operable to control or assist in controlling the removal of the first insulative material from the first insulative material layers 204 in the isotropic etching process. It is also recognized in the present disclosure that the conductive material layers 206 above and/or below the removed first insulative material layers 204 are held or secured in place by at least the vertical second insulative material structures 212a.

The bit lines of the 3D GAA VG structure may be formed (e.g., action 207) in the identified bit line locations 208 by first performing a rounding of at least a portion of the conductive material layers 206 along the identified bit line locations 208. In this regard, a cross section of the conductive material layers 206 after the rounding may resemble rectangles with rounded corners, ovals, and may also take any other shape or form. Thereafter, as illustrated in FIG. 2H, the bit lines may be formed by forming a charge storage layer 206′ over at least a portion of the rounded conductive material layers 206. The charge storage layer 206′ may be formed as an oxide-nitride-oxide (ONO) layer or multilayer in example embodiments. In example embodiments, the charge storage layer 206′ may comprise a tunnel oxide layer 206a formed over the rounded conductive material layer 206. The charge storage layer 206′ may further comprise a charge trapping nitride layer 206b formed over the tunnel oxide layer 206a. The charge storage layer 206′ may further comprise a block oxide layer 206c formed over the charge trapping nitride layer 206b. A thickness of the tunnel oxide layer 206a may be between about 2 to 6 nm. A thickness of the block oxide layer 206c may be between about 7 to 12 nm.

In action 209, the word lines 214 may be formed in the identified word line locations 210. This may be achieved by depositing conductive material into the removed portions 214′ in the identified word line locations 210 that are outside of the identified bit line locations 208, as illustrated in FIG. 2I. The formed word lines may then be connected (not shown) so as to form the 3D GAA VG structure or device.

In example embodiments, the vertical second insulative material structures 212a may be replaced with first insulative material so as to form vertical first insulative material structures 212b (e.g., action 211). This may be achieved by first removing the second insulative material from the second insulative material structures 212a, followed by depositing first insulative material in the aforementioned removed portions. Vertical first insulative material structures 212b are illustrated in FIG. 2J.

### Second Example Embodiment

(1) Providing a Substrate (e.g., Action 101).

As described in action 101 of FIG. 1, substrates 202 appropriate for use in semiconductor devices and structures may be obtained by any one or more manufacturing methods, such as pressing methods, float methods, down-drawn methods, redrawing methods, fusion methods, and/or the like.

(2) Forming a Plurality of Alternating First Insulative Material Layers and Conductive Material Layers (e.g., Action 103).

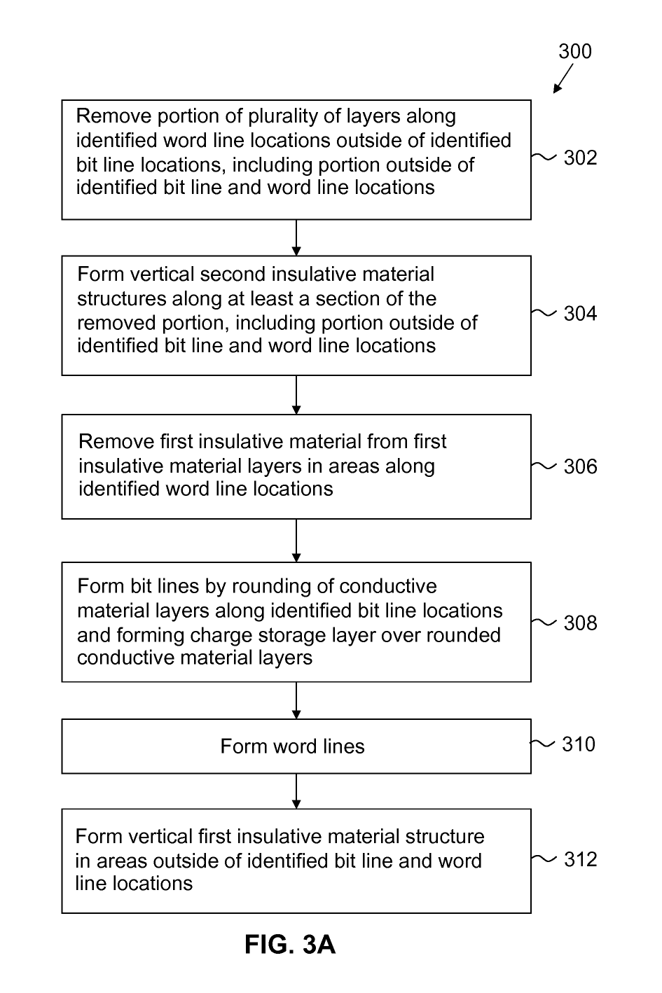

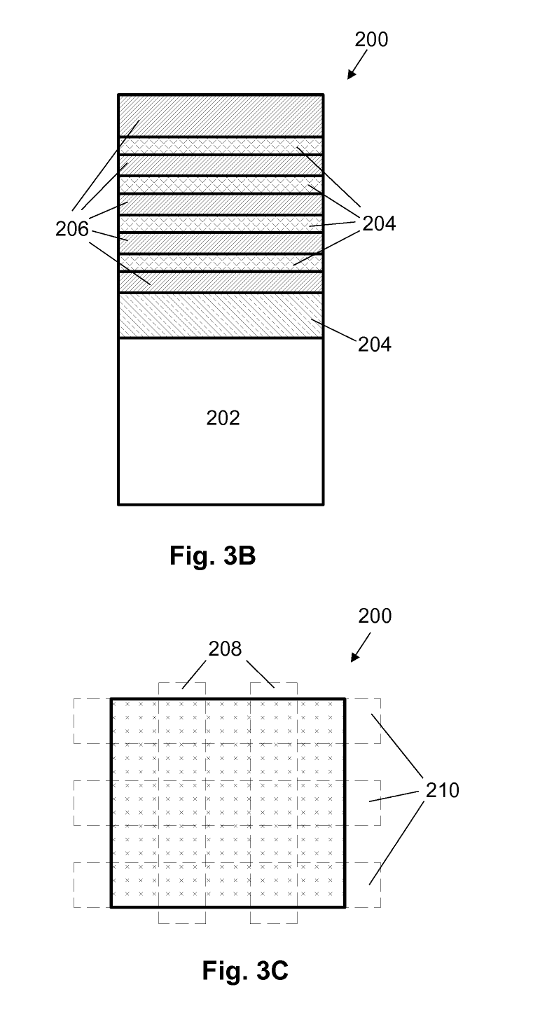

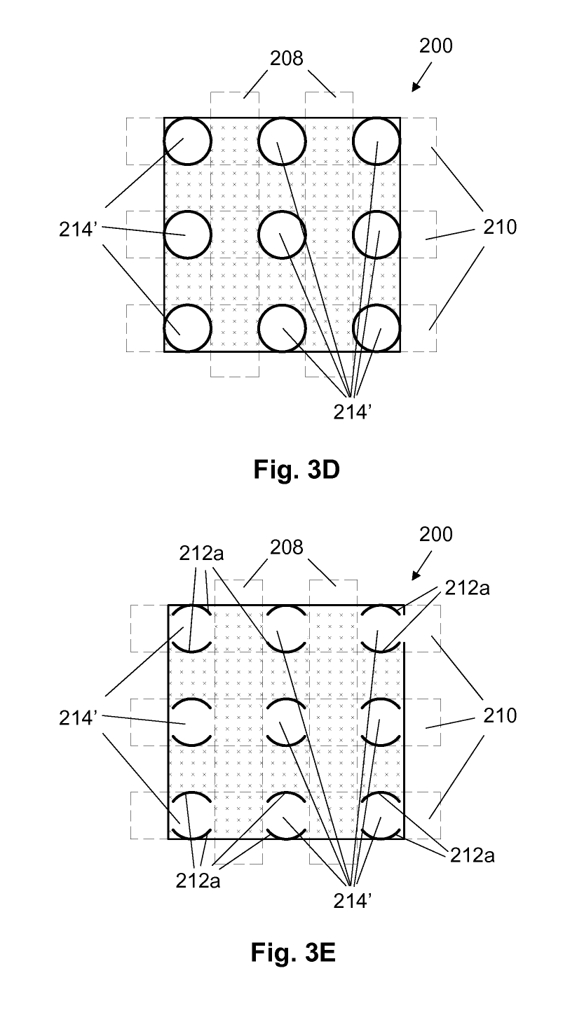

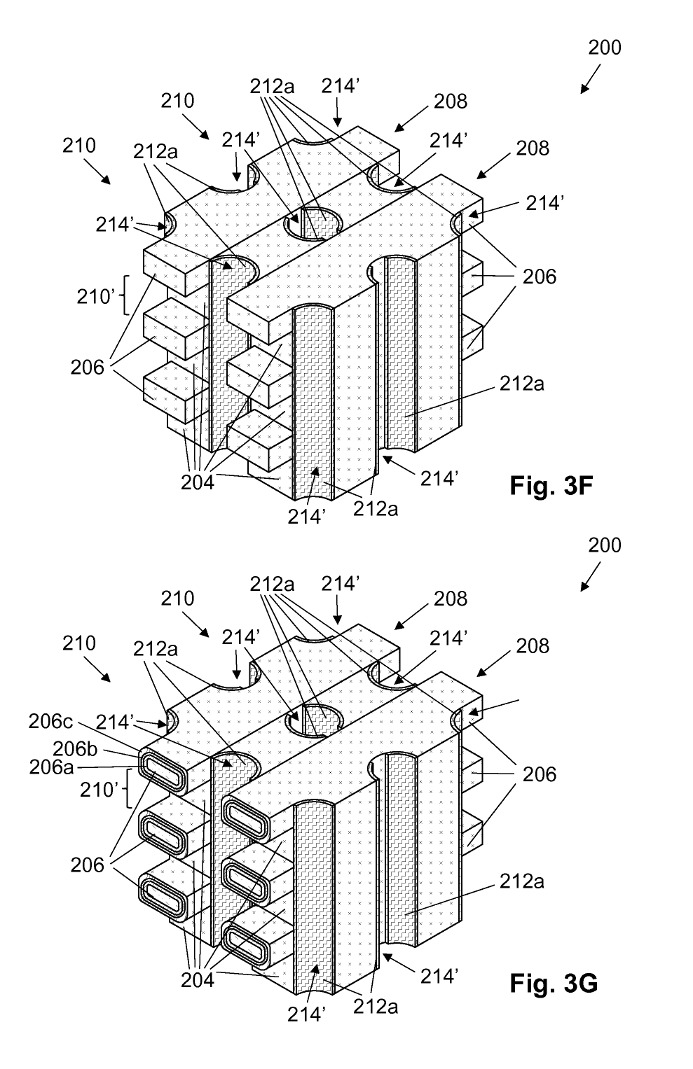

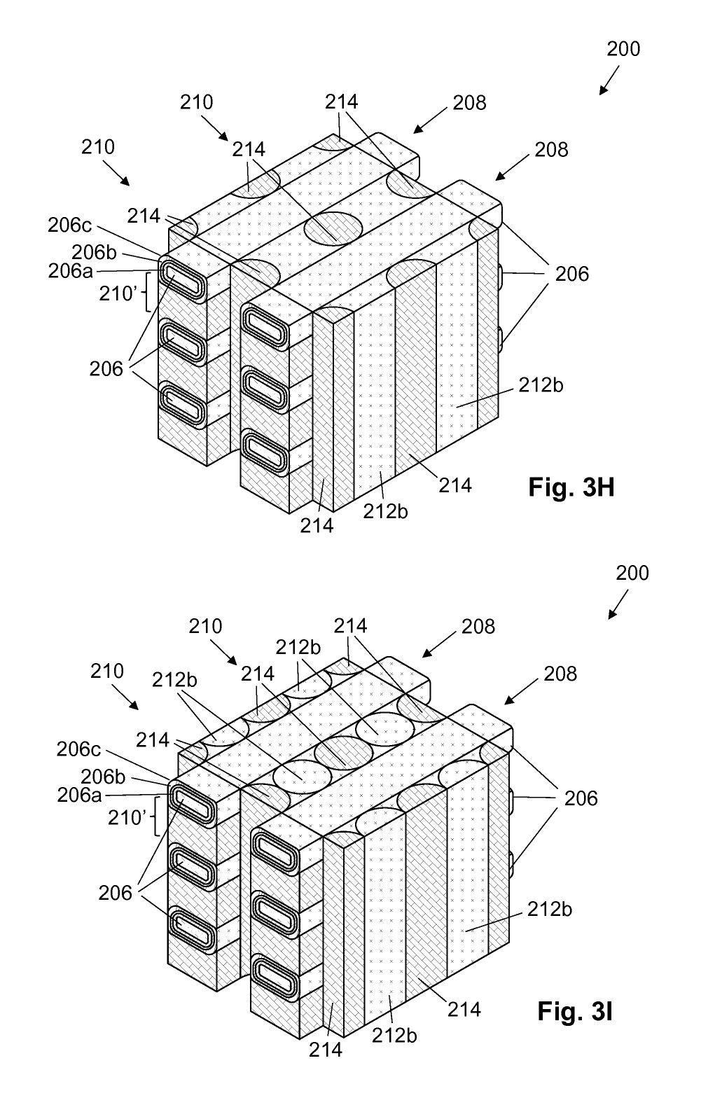

As described in action 103 of FIG. 1, a substrate 202, such as one obtained from the above action 101, may be provided with alternating first insulative material layers 204 and conductive material layers 206 thereon (e.g., action 103), as illustrated in the cross-sectional view of FIG. 3B. The first insulative materials may include oxides, and the like, and the conductive materials may include polysilicon, or the like. The thickness of each of the first insulative material layers 204 may be about 600 Angstroms. It is recognized herein that the thickness of each of the first insulative material layers 204 may be about 500-700 Angstroms in example embodiments. The thickness of each of the conductive material layers 206 may be about 200 Angstroms. It is recognized herein that the thickness of each of the conductive material layers 206 may be about 100-300 Angstroms in example embodiments.

(3) Identifying Word Line and Bit Line Locations (e.g., Action 105).

As described in action 105 of FIG. 1, a substrate 202 having alternating first insulative material layers 204 and conductive material layers 206 formed thereon may be subjected to an identification (or planning or designing) process whereby bit line locations 208 and word line 210 locations are identified (or planned or designed) for subsequent actions (as described below and herein), including the forming of bit lines 208, word lines 210, and vertical first insulative material structures provided substantially or mostly outside of identified bit line and word line locations. An example identification of bit line 208 and word line 210 locations is illustrated in the top view illustration of FIG. 3C.

(4) Forming 3D GAA VG Structures, Including Bit Lines and Word Lines (e.g., Actions 301, 303, 305, 307, 309, and 311).

Reference is now made to the sequence of actions of FIG. 3A. The 3D GAA VG structures may be fabricated by removing portions 214′ of the plurality of layers in areas along the identified word line locations 210 that are outside of the identified bit line locations 208 (e.g., action 301), and may also include portions that are inside of the identified bit line locations 208. The removed portions 214′ are illustrated in FIG. 3D. Each of these removed portions 214′ may extend through the plurality of layers to at least a top surface of the substrate 202. Although the removed portions 214′ are illustrated in FIG. 3D as resembling circular or cylindrical holes, it is to be understood in the present disclosure that the removed portions 214′ may be in other shapes and/or forms, including squares, rectangles, ovals, etc.

Vertical second insulative material structures 212a may be formed outside of the identified bit line locations 208 and word line locations 210 (e.g., action 303), as illustrated in FIG. 3E. This may be accomplished by first forming a layer of second insulative material 212a′ over the inner surface of the removed portions 214′, followed by removing or etching portions of the second insulative material facing or within the identified bit line locations 208 so as to arrive at the vertical second insulative material structures 212a (as illustrated in FIG. 3E). Although the layer of second insulative material 212a′ are illustrated in FIG. 3E as resembling circular or cylindrical rings (and the vertical second insulative material structures 212a resemble portions of rings), it is to be understood in the present disclosure that the layer of second insulative material 212a′ (and vertical second insulative material structures 212a) may be in other shapes and/or forms, including squares, rectangles, ovals, etc. (and portions thereof for the vertical second insulative material structures 212a).

In an example embodiment, the second insulative material may be any insulative or dielectric material, such as an oxide, that differs from the first insulative material, such as a nitride, and vice versa, that allows an easy removal of either the first or second insulative material without removing the other.

In action 305, portions 210′ of the first insulative material in the first insulative material layers that are along the identified word line locations 210 may be removed. This is illustrated in FIG. 3F. The aforementioned removal may be achieved by performing an isotropic etching process to remove the first insulative material from the first insulative material layers 204 in areas along the identified word line locations 210. It is recognized in the present disclosure that the vertical second insulative material structures 212a may be operable to control or assist in controlling the removal of the first insulative material from the first insulative material layers 204 in the isotropic etching process. It is also recognized in the present disclosure that the conductive material layers 206 above and/or below the removed first insulative material layers 204 are held or secured in place by at least the remaining first insulative material in the first insulative material layers 204 outside of the identified word line locations 210, as well as the vertical second insulative material structures 212a.

The bit lines of the 3D GAA VG structure may be formed (e.g., action 307) in the identified bit line locations 208 by first performing a rounding of at least a portion of the conductive material layers 206 along the identified bit line locations 208. In this regard, a cross section of the conductive material layers 206 after the rounding may resemble rectangles with rounded corners, ovals, and may also take any other shape or form. Thereafter, as illustrated in FIG. 3G, the bit lines may be formed by forming a charge storage layer 206′ over at least a portion of the rounded conductive material layers 206. The charge storage layer 206′ may be formed as an oxide-nitride-oxide (ONO) layer or multilayer in example embodiments. In example embodiments, the charge storage layer 206′ may comprise a tunnel oxide layer 206a formed over the rounded conductive material layer 206. The charge storage layer 206′ may further comprise a charge trapping nitride layer 206b formed over the tunnel oxide layer 206a. The charge storage layer 206′ may further comprise a block oxide layer 206c formed over the charge trapping nitride layer 206b. A thickness of the tunnel oxide layer 206a may be between about 2 to 6 nm. A thickness of the block oxide layer 206c may be between about 7 to 12 nm.

In action 309, the word lines may be formed in the identified word line locations 210. This may be achieved by depositing conductive material 214 into the removed portions 214′ in the identified word line locations 210 that are outside of the identified bit line locations 208, as illustrated in FIG. 3H. The formed word lines may then be connected (not shown) so as to form the 3D GAA VG structure or device.

In example embodiments, vertical first insulative material structures 212b may be formed in areas outside of the identified bit line locations 208 and word line locations 210 (e.g., action 311). This is illustrated in FIG. 3I.

### Third Example Embodiment

(1) Providing a Substrate (e.g., Action 101).

As described in action 101 of FIG. 1, substrates 202 appropriate for use in semiconductor devices and structures may be obtained by any one or more manufacturing methods, such as pressing methods, float methods, down-drawn methods, redrawing methods, fusion methods, and/or the like.

(2) Forming a Plurality of Alternating First Insulative Material Layers and Conductive Material Layers (e.g., Action 103).

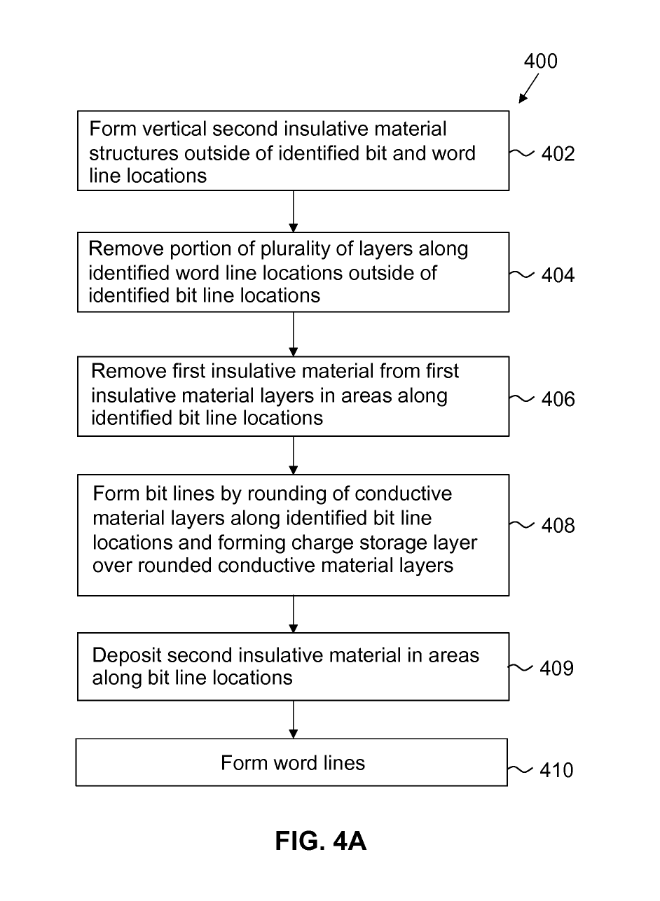

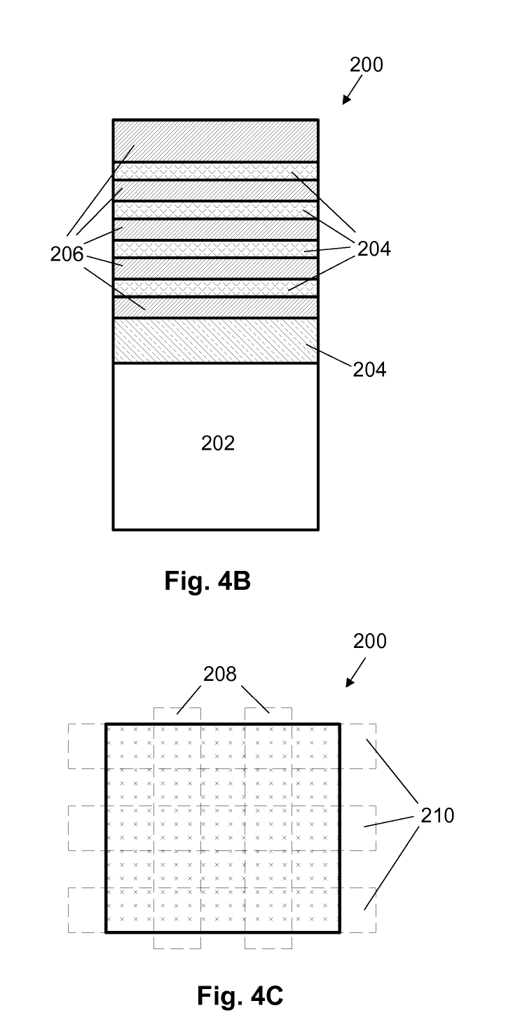

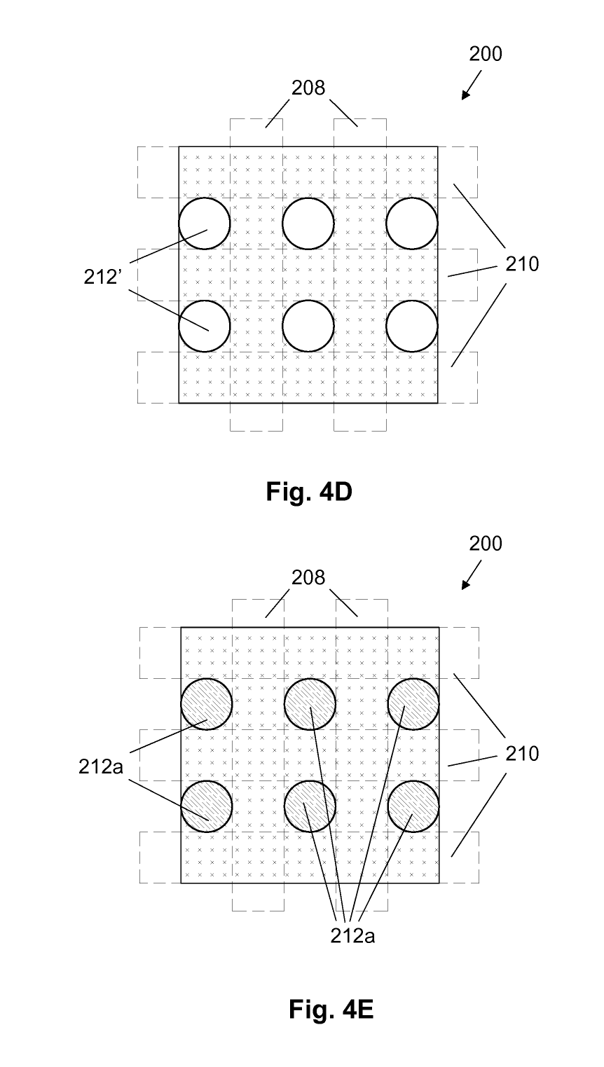

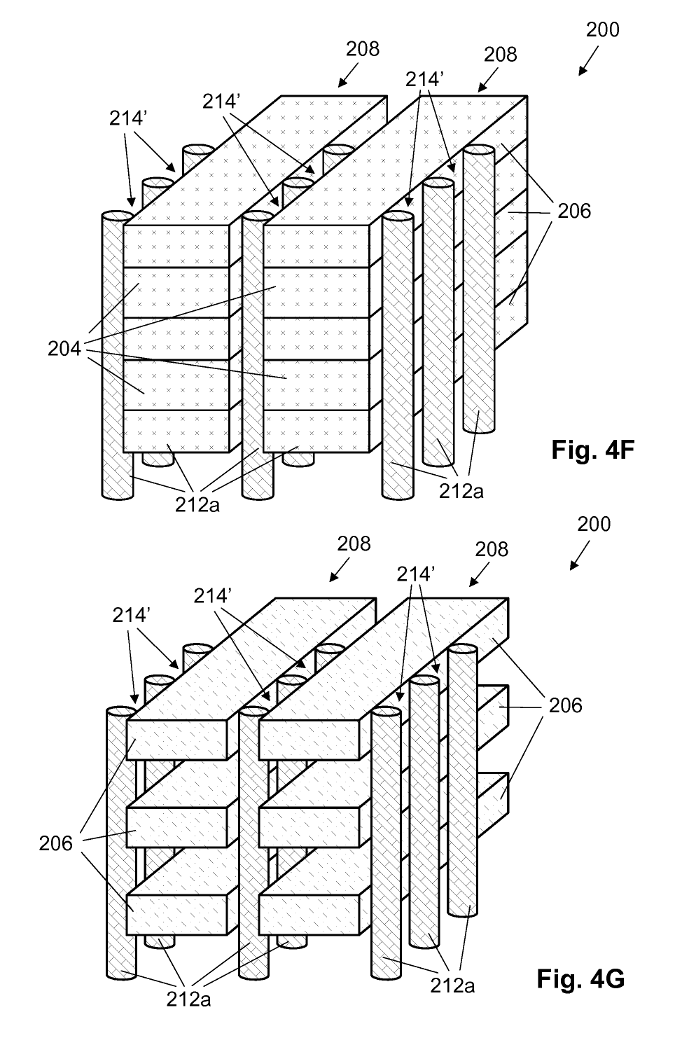

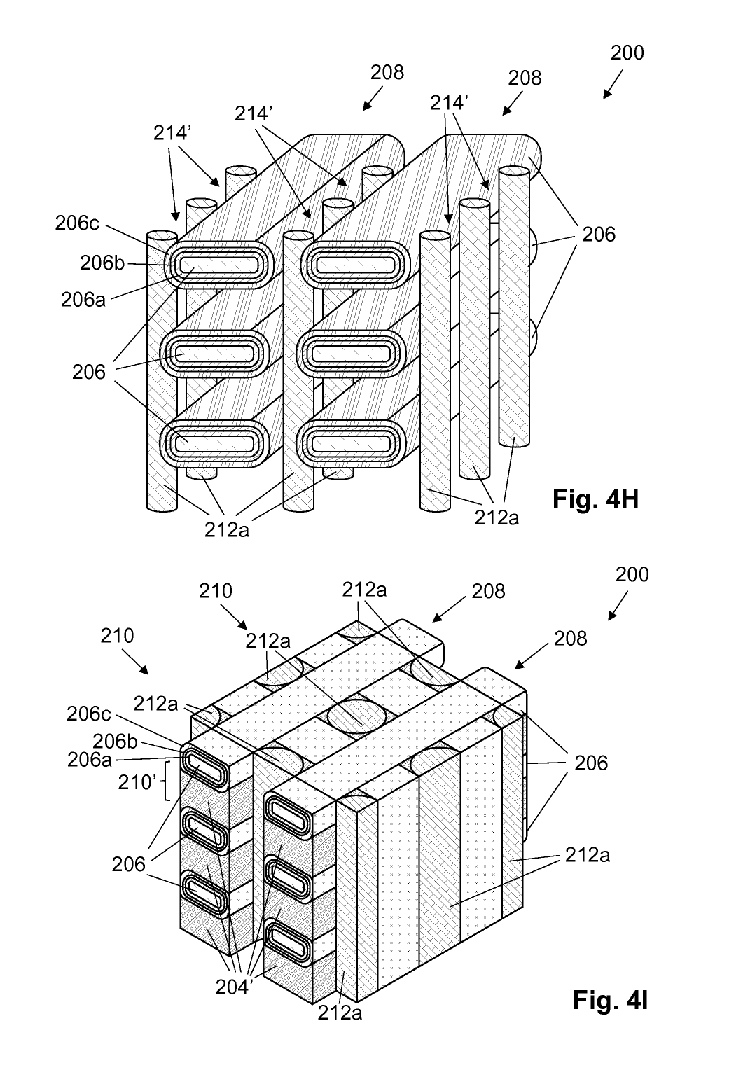

As described in action 103 of FIG. 1, a substrate 202, such as one obtained from the above action 101, may be provided with alternating first insulative material layers 204 and conductive material layers 206 thereon (e.g., action 103), as illustrated in the cross-sectional view of FIG. 4B. The first insulative materials may include nitrides, and the like, and the conductive materials may include polysilicon, or the like. The thickness of each of the first insulative material layers 204 may be about 600 Angstroms. It is recognized herein that the thickness of each of the first insulative material layers 204 may be about 500-700 Angstroms in example embodiments. The thickness of each of the conductive material layers 206 may be about 200 Angstroms. It is recognized herein that the thickness of each of the conductive material layers 206 may be about 100-300 Angstroms in example embodiments.

(3) Identifying Word Line and Bit Line Locations (e.g., Action 105).

As described in action 105 of FIG. 1, a substrate 202 having alternating first insulative material layers 204 and conductive material layers 206 formed thereon may be subjected to an identification (or planning or designing) process whereby bit line locations 208 and word line 210 locations are identified (or planned or designed) for subsequent actions (as described below and herein), including the forming of bit lines 208, word lines 210, and vertical first insulative material structures provided substantially or mostly outside of identified bit line and word line locations. An example identification of bit line 208 and word line 210 locations is illustrated in the top view illustration of FIG. 4C.

(4) Forming 3D GAA VG Structures, Including Bit Lines and Word Lines (e.g., Actions 401, 403, 405, 407, 409, and 411).

Reference is now made to the sequence of actions of FIG. 4A. The 3D GAA VG structures may be fabricated by forming vertical second insulative material structures 212a outside of the identified bit line locations 208 and word line locations 210 (e.g., action 401). This may be accomplished by first removing portions 212′ of the plurality of layers outside of the identified bit line locations 208 and word line locations 210, as illustrated in FIG. 4D. Each of these removed portions 212′ may extend through the plurality of layers to at least a top surface of the substrate 202. Although the removed portions 212′ are illustrated in FIG. 4D as resembling circular or cylindrical holes, it is to be understood in the present disclosure that the removed portions 212′ may be in other shapes and/or forms, including squares, rectangles, ovals, etc. Thereafter, as illustrated in FIG. 4E, the vertical second insulative material structures 212a may be formed in areas outside of the identified bit line locations 208 and word line locations 210 by depositing second insulative material in the aforementioned removed portions 212′ depicted in FIG. 4D. In an example embodiment, the second insulative material may be any insulative or dielectric material, such as an oxide, that differs from the first insulative material, such as a nitride, and vice versa, that allows an easy removal of either the first or second insulative material without removing the other.

As illustrated in FIG. 4F, portions 214′ of the plurality of layers in areas outside of the identified bit line locations 208 and outside of the vertical second insulative material structures 212a may be removed (e.g., action 403). Each of these removed portion 214′ may extend through the plurality of layers to at least a top surface of the substrate 202.

In action 405, the remaining portions of the first insulative material in the first insulative material layers 204 may be removed. This is illustrated in FIG. 4G. The aforementioned removal may be achieved by performing an isotropic etching process to remove the remaining first insulative material from the first insulative material layers 204. It is recognized in the present disclosure that the conductive material layers 206 above and/or below the removed first insulative material layers 204 are held or secured in place by at least the vertical second insulative material structures 212a.

The bit lines of the 3D GAA VG structure may be formed (e.g., action 407) in the identified bit line locations 208 by first performing a rounding of at least a portion of the conductive material layers 206 along the identified bit line locations 208. In this regard, a cross section of the conductive material layers 206 after the rounding may resemble rectangles with rounded corners, ovals, and may also take any other shape or form. Thereafter, as illustrated in FIG. 4H, the bit lines may be formed by forming a charge storage layer 206′ over at least a portion of the rounded conductive material layers 206. The charge storage layer 206′ may be formed as an oxide-nitride-oxide (ONO) layer or multilayer in example embodiments. In example embodiments, the charge storage layer 206′ may comprise a tunnel oxide layer 206a formed over the rounded conductive material layer 206. The charge storage layer 206′ may further comprise a charge trapping nitride layer 206b formed over the tunnel oxide layer 206a. The charge storage layer 206′ may further comprise a block oxide layer 206c formed over the charge trapping nitride layer 206b. A thickness of the tunnel oxide layer 206a may be between about 2 to 6 nm. A thickness of the block oxide layer 206c may be between about 7 to 12 nm.

Second insulative material 204′ may be deposited in the first insulative material layers within the identified bit line locations 208 so as to provide electrical isolation between consecutive bit lines, as illustrated in FIG. 4I.

In action 411, the word lines may be formed in the identified word line locations 210. This may be achieved by depositing conductive material into the identified word line locations 210 that are outside of the identified bit line locations 208, as illustrated in FIG. 41. The formed word lines may then be connected (not shown) so as to form the 3D GAA VG structure or device.

It is to be understood in the present disclosure that the charge storage structure may include oxide-nitride-oxide, silicon-oxide-nitride-oxide-silicon (SONOS), or BE-SONOS structures, including those comprising a tunneling dielectric layer, a trapping layer, and a blocking oxide layer. The tunneling dielectric layer may comprise oxide, nitride, and oxide sub-layers and/or a composite of materials forming an inverted “U” shaped valence band under zero bias voltage; the trapping layer may comprise nitride; and the blocking oxide or gate layer may comprise oxide. The tunneling dielectric layer may further include a hole tunneling layer, a band offset layer, and an isolation layer. Other internal structures are also contemplated in this disclosure, including those for floating gate memory, charge trapping memory, NAND-type devices, semiconductor devices other than NAND-type devices, non-volative memory devices, and/or embedded memory devices.

While various embodiments in accordance with the disclosed principles have been described above, it should be understood that they have been presented by way of example only, and are not limiting. Thus, the breadth and scope of the example embodiments described in the present disclosure should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

For example, as referred to in the present disclosure, “forming” a layer, plurality of layers, plurality of alternating layers, multilayer, stack, and/or structure may include any method of creating the layer, multilayer, and/or structure, including depositing and the like. A “multilayer” may be one layer, structure, and/or stack comprising a plurality of internal layers and/or a plurality of layers, multilayers, structures, and/or stacks stacked or formed on or over one another. Internal structures may include any internal structure of a semiconductor device, including charge storage structures such as silicon-oxide-nitride-oxide-silicon (SONOS) or bandgap engineered silicon-oxide-nitride-oxide-silicon (BE-SONOS) structures comprising a tunneling dielectric layer, a trapping layer, and a blocking oxide layer.

Although one or more layers, multilayers, and/or structures may be described in the present disclosure as being “silicon,” “polysilicon,” “conductive,” “oxide,” and/or “insulative” layers, multilayers, and/or structures, it is to be understood that example embodiments may be applied for other materials and/or compositions of the layers, multilayers, and/or structures. Furthermore, such structures may be in the form of a crystalline structure and/or amorphous structure in example embodiments.

Furthermore, “patterning” of one or more layers, multilayers, and/or structures may include any method of creating a desired pattern on the one or more layers, multilayers, and/or structures, including performing a photolithography process by applying a photoresist mask (not shown) having pre-formed patterns and etching the layers, multilayers, and/or structures according to the pre-formed patterns on the photoresist mask.

“Stringers” formed, deposited, and/or remaining in and/or on material(s), layer(s), structure(s), and/or between materials, layers, and/or structures may include conductive material, insulative material, and materials having openings, bores, gaps, voids, cracks, holes, bubbles, and the like, and/or a mixture thereof. Furthermore, although the present disclosure describes example embodiments for addressing “stringers,” the claimed approaches described in the present disclosure may also be beneficially applicable to address and/or improve other performance-related problems and/or issues, including formation, shifting, changing in size, changing in shape, changing in composition, combining, dividing, and/or migrating of other types of imperfections in the semiconductor fabrication process.

“Elongated posts” or “posts” may be formed, filled, constructed, deposited, and/or structured using one or more of a plurality of materials, including insulative materials, conductive materials, nitrides, and the like, and a cross-section of the elongated posts may be formed in one or more of a plurality of shapes, including a circle, an oval, a square, a rectangle, a triangle, and/or a combination of geometric shapes.

It is to be understood in the present disclosure that the principles described can be applied outside the context of NAND-type devices described in exemplary embodiments, including NOR-type devices, other memory storage devices, floating gate memory devices, charge trapping memory devices, non-volatile memory devices, and/or embedded memory devices.

Various terms used herein have special meanings within the present technical field. Whether a particular term should be construed as such a “term of art” depends on the context in which that term is used. “Connected to,” “forming on,” “forming over,” or other similar terms should generally be construed broadly to include situations where formations, depositions, and connections are direct between referenced elements or through one or more intermediaries between the referenced elements. These and other terms are to be construed in light of the context in which they are used in the present disclosure and as one of ordinary skill in the art would understand those terms in the disclosed context. The above definitions are not exclusive of other meanings that might be imparted to those terms based on the disclosed context.

Words of comparison, measurement, and timing such as “at the time,” “equivalent,” “during,” “complete,” and the like should be understood to mean “substantially at the time,” “substantially equivalent,” “substantially during,” “substantially complete,” etc., where “substantially” means that such comparisons, measurements, and timings are practicable to accomplish the implicitly or expressly stated desired result.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method of fabricating a three-dimensional gate-all-around (GAA) vertical gate (VG) semiconductor structure, the method comprising:
providing a substrate;
forming a plurality of layers over the substrate, the plurality of layers having alternating first insulative material layers and conductive material layers, the first insulative material layers formed by a deposition of first insulative material and the conductive material layers formed by a deposition of conductive material;
identifying bit line and word line locations for the formation of bit lines and word lines;
removing portions of the plurality of layers outside of the identified bit line and word line locations, each said removed portion extending through the plurality of layers to at least a top surface of the substrate;
forming vertical second insulative material structures in areas outside of the identified bit line and word line locations;
removing portions of the plurality of layers in areas along the identified word line locations outside of the identified bit line locations, each said removed portion extending through the plurality of layers to at least a top surface of the substrate;
remove the first insulative material from the first insulative material layers in areas along the identified word line locations;
forming bit lines in the identified bit line locations by:
rounding at least a portion of each of the conductive material layers along the identified bit line locations; and
forming a charge storage layer over at least a portion of the rounded conductive material layers; and
forming word lines in the identified word line locations.

2. The method of claim 1, wherein the first insulative material is removed from the first insulative material layers by performing an isotropic etching process.

3. The method of claim 1, wherein the vertical second insulative material structures are formed extending to at least a top surface of the substrate.

4. The method of claim 1, wherein the vertical second insulative material structures are operable to control the removal of the first insulative material in the isotropic etching process.

5. The method of claim 1, wherein the charge storage layer is an oxide-nitride-oxide layer.

6. The method of claim 1, wherein the charge storage layer comprises a tunnel oxide layer formed over the rounded conductive material layer, a charge trapping nitride layer formed over the tunnel oxide layer, and a block oxide layer formed over the charge trapping nitride layer.

7. The method of claim 6, wherein a thickness of the tunnel oxide layer is between about 2 to 6 nm.

8. The method of claim 6, wherein a thickness of the block oxide layer is between about 7 to 12 nm.

9. The method of claim 1, wherein the forming the word lines comprises a deposition of conductive material in areas along the identified word line locations outside of the identified bit line locations.

10. The method of claim 1, wherein each of the removed portions of the plurality of layers resembles a hole in the plurality of layers.

11. The method of claim 10, wherein each of the vertical second insulative material structures are formed by a deposition of second insulative material in the holes.

12. The method of claim 1, further comprising connecting the word lines.

13. The method of claim 1, wherein the first insulative material and the second insulative material are selecting in such a way that the isotropic etching process is operable to remove the first insulative material but not the second insulative material.

14. The method of claim 1, wherein the first insulative material is an oxide material and the second insulative material is a nitride material.

15. The method of claim 1, wherein the first insulative material is a nitride material and the second insulative material is an oxide material.

16. A semiconductor device formed by the method of claim 1.

17. A semiconductor structure comprising:
a three-dimensional gate-all-around (GAA) vertical gate (VG) structure having a plurality of bit lines and word lines formed over a substrate; and
a plurality of first insulative material portions extending vertically from at least a top surface of the substrate, the plurality of first insulative material portions formed adjacent to the three-dimensional vertical gate structure and operable to provide electrical isolation between adjacent word lines of the three-dimensional GAA VG structure.

18. The semiconductor structure of claim 17, wherein each of the bit lines comprise:
a rounded conductive material core; and
a charge storage layer formed over the conductive material core.

19. The semiconductor structure of claim 18, wherein the charge storage layer is an oxide-nitride-oxide layer.

20. The semiconductor structure of claim 17, wherein the three-dimensional GAA VG structure is formed by:
forming a plurality of layers over the substrate, the plurality of layers having alternating first insulative material layers and conductive material layers, the first insulative material layers formed by a deposition of first insulative material and the conductive material layers formed by a deposition of conductive material;
identifying bit line and word line locations for the formation of bit lines and word lines;
removing portions of the plurality of layers outside of the identified bit line and word line locations, the said removed portions extending through the plurality of layers to at least a top surface of the substrate.

21. The semiconductor structure of claim 20, wherein the three-dimensional GAA VG structure is further formed by:
forming vertical second insulative material structures in areas outside of the identified bit line and word line locations.

22. The semiconductor structure of claim 20, wherein the three-dimensional GAA VG structure is further formed by:
removing portions of the plurality of layers in areas along the identified word line locations outside of the identified bit line locations, the said removed portions extending through the plurality of layers to at least a top surface of the substrate.

23. The semiconductor structure of claim 20, wherein the three-dimensional GAA VG structure is further formed by:
performing an isotropic etching process to remove the first insulative material from the first insulative material layers along the identified word line locations.

24. The semiconductor structure of claim 20, wherein the three-dimensional GAA VG structure is further formed by:
forming bit lines in the identified bit line locations by:
rounding at least a portion of each of the conductive material layers along the identified bit line locations; and
forming a charge storage layer over at least a portion of the rounded conductive material layers.

25. The semiconductor structure of claim 20, wherein the three-dimensional GAA VG structure is further formed by:
forming word lines in the identified word line locations by depositing conductive material in areas along the identified word line locations outside of the identified bit line locations.

26. The semiconductor structure of claim 18, wherein the charge storage layer comprises a tunnel oxide layer formed over the rounded conductive material layer, a charge trapping nitride layer formed over the tunnel oxide layer, and a block oxide layer formed over the charge trapping nitride layer.

27. The semiconductor structure of claim 26, wherein a thickness of the tunnel oxide layer is between about 2 to 6 nm.

28. The semiconductor structure of claim 26, wherein a thickness of the block oxide layer is between about 7 to 12 nm.
